(19) United States
(12) Patent Application Publication
(10) Pub. No.: US 2026/0040915 A1
(43) Pub. Date: Feb. 5, 2026

(54) SEMICONDUCTOR PACKAGE

(71) Applicant: Samsung Electronics Co., Ltd., Suwon-si (KR)

(72) Inventors: Hyeonjeong HWANG, Suwon-si (KR); Junghoon KANG, Suwon-si (KR); Hyunsoo CHUNG, Suwon-si (KR)

(21) Appl. No.: 19/053,699

(22) Filed: Feb. 14, 2025

(30) Foreign Application Priority Data
Aug. 1, 2024 (KR) 10-2024-0102566

(51) Int. Cl. H01L 23/00; H01L 23/31; H01L 23/48; H01L 23/498; H01L 25/16; H10B 80/00; H10D 80/30

(52) U.S. Cl. CPC H01L 24/08; H01L 23/481; H01L 23/49894; H01L 23/564; H01L 25/16; H01L 23/3185; H01L 24/16; H01L 24/80; H01L 24/96; H01L 24/97; H01L 2224/08145; H01L 2224/16225; H01L 2224/80203; H01L 2224/80895; H01L 2224/80896; H01L 2224/96; H01L 2224/97; H01L 2225/06517; H01L 2225/06544; H01L 2924/14361; H10B 80/00; H10D 80/30

(57) ABSTRACT

Provided is a semiconductor package including a first semiconductor chip, a plurality of second semiconductor chips stacked on the first semiconductor chip, a step cover layer surrounding side surfaces of the plurality of second semiconductor chips and covering side portions of the plurality of second semiconductor chips, wherein a maximum thickness of the step cover layer is 40 micrometers (μm) or less, and a moisture barrier layer covering an outer surface of the step cover layer.

### CROSS-REFERENCE TO RELATED APPLICATION

This application claims priority to Korean Patent Application No. 10-2024-0102566, filed in the Korean Intellectual Property Office on Aug. 1, 2024, the entire contents of which are hereby incorporated by reference.

### BACKGROUND

### Technical Field

The present disclosure relates to a semiconductor package.

### Description of Related Art

Semiconductor devices are used as key components of various electronic devices such as computers, smartphones, automobiles, medical devices, etc. Various external factors such as temperature change, humidity, electromagnetic interference, power fluctuations, etc. may affect the operation of semiconductor devices, and accordingly, it is very important to design and manufacture the semiconductor devices to operate normally even in various environments.

For this reason, after a semiconductor package is manufactured, tests may be performed under various environmental stresses (e.g., high temperature, high humidity, electrical stress conditions). By simulating the various conditions that the semiconductor package may encounter in actual use environments through these tests, the durability and stability of the semiconductor package may be verified.

### SUMMARY

In order to address the above and other concerns, the present disclosure provides a semiconductor package with improved reliability.

According to some aspects, a semiconductor package may include a first semiconductor chip, a plurality of second semiconductor chips stacked on the first semiconductor chip, a step cover layer surrounding side surfaces of the plurality of second semiconductor chips and covering side portions of the plurality of second semiconductor chips, wherein a maximum thickness of the step cover layer is 40 micrometers (μm) or less, and a moisture barrier layer covering an outer surface of the step cover layer.

According to some aspects, a semiconductor package may include a first semiconductor chip, a second semiconductor chip disposed on the first semiconductor chip, a step cover layer surrounding side surfaces of the first semiconductor chip and the second semiconductor chip, and covering side portions of the first semiconductor chip and the second semiconductor chip, wherein a maximum thickness of the step cover layer is 40 micrometers (μm) or less, and a moisture barrier layer covering an outer surface of the step cover layer.

According to some aspects, a semiconductor package may include a first semiconductor chip, a plurality of second semiconductor chips stacked on the first semiconductor chip, a dummy chip disposed on the plurality of second semiconductor chips, a step cover layer including an organic material, in which the step cover layer may surround side of the plurality of second semiconductor chips, a side surface of the dummy chip, and an upper surface of the dummy chip, and may cover side portions of the plurality of second semiconductor chips, a moisture barrier layer including an inorganic material, in which the moisture barrier layer may cover an outer surface of the step cover layer, and a molding member including a second organic material, in which the molding member covers an outer surface of the moisture barrier layer, in which the step cover layer may cover a side surface of the plurality of second semiconductor chips and a stepped surface exposed by a side step between the plurality of second semiconductor chips.

According to some aspects of the present disclosure, because penetration of moisture into the semiconductor package (e.g., between the chip-to-chip bonding layers) is prevented by the moisture barrier layer, the semiconductor package may operate stably under environmental stress (e.g., under test conditions such as high temperature, high humidity, electrical stress, etc.). For example, the reliability of the semiconductor package may be improved.

According to some aspects, the step cover layer is configured to cover the side step that may occur on side portions of semiconductor chips, so that the moisture barrier layer can be uniformly applied without lifting even when there is a step between the semiconductor chips. Accordingly, moisture penetration into the semiconductor package may be prevented even when there is a step between the second semiconductor chips.

The effects of the present disclosure are not limited to the effects described above, and other effects not described herein can be clearly understood by those of ordinary skill in the art (referred to as “ordinary technician”) from the description of the claims.

### BRIEF DESCRIPTION OF THE DRAWINGS

The above and other objects, features and advantages of the present disclosure will be described with reference to the accompanying drawings described below, where similar reference numerals indicate similar elements, but not limited thereto, in which:

FIG. 1 illustrates an example of a semiconductor package;

FIGS. 2 and 3 are enlarged views illustrating an example of an area A of FIG. 1 during a test on a semiconductor package;

FIG. 4 illustrates an example of a semiconductor package;

FIG. 5 illustrates an example of a semiconductor package, according to embodiments of the present disclosure;

FIG. 6 is an enlarged view of an area B of FIG. 5;

FIG. 7 illustrates an example of a semiconductor package, according to embodiments of the present disclosure;

FIG. 8 illustrates an example of a semiconductor package, according to embodiments of the present disclosure;

FIGS. 9 to 20 are diagrams illustrating an example of a process of manufacturing a semiconductor package;

FIG. 21 illustrates an example of a semiconductor package;

FIG. 22 is a diagram provided to explain an example implementation of a semiconductor package; and

FIG. 23 illustrates an example of a semiconductor package.

### DETAILED DESCRIPTION OF THE EMBODIMENTS

Hereinafter, example details for the practice of the present disclosure will be described in detail with reference to the accompanying drawings. However, in the following description, detailed description of well-known functions or configurations will be omitted when it may make the subject matter of the present disclosure rather unclear.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Items described in the singular herein may be provided in plural, as can be seen, for example, in the drawings. Thus, the description of a single item that is provided in plural should be understood to be applicable to the remaining plurality of items unless context indicates otherwise.

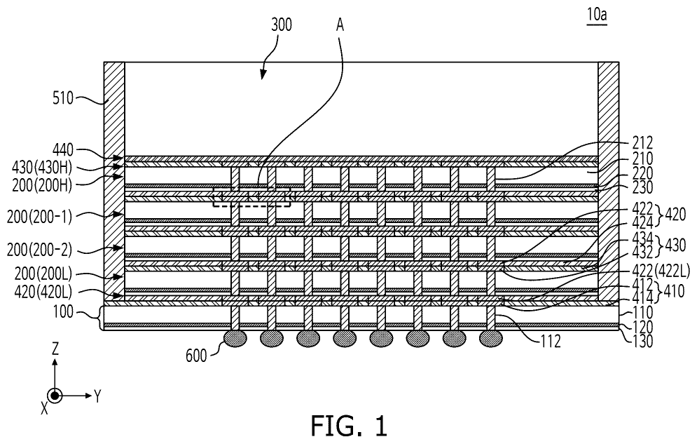

FIG. 1 is a diagram illustrating an example of a semiconductor package 10a. Referring to FIG. 1, the semiconductor package 10a may include a first semiconductor chip 100 and a plurality of second semiconductor chips 200 arranged on the first semiconductor chip 100. The first semiconductor chip 100 and/or the plurality of second semiconductor chips 200 may include, e.g., a memory chip and/or memory cells. Although FIG. 1 illustrates that the semiconductor package 10a includes four second semiconductor chips 200 stacked on the first semiconductor chip 100, aspects are not limited thereto, and the semiconductor package 10a may include any number of second semiconductor chips 200 stacked on the first semiconductor chip 100. In this example, the second semiconductor chips 200 may be stacked on the first semiconductor chip 100 along a vertical direction (e.g., a Z direction), and may extend along a horizontal direction (e.g., a Y direction) perpendicular to the vertical direction.

The first semiconductor chip 100 may include a first semiconductor substrate 110, one or more first through electrodes 112 formed through the first semiconductor substrate 110, a first device layer 120, and a first wiring layer 130.

For example, the first semiconductor substrate 110 may include silicon (Si) or germanium (Ge), but is not limited thereto. For example, the first semiconductor substrate 110 may include a material having properties similar to silicon or germanium, such as silicon germanium (SiGe), indium antimonide (InSb), lead telluride compound (PbTe), indium arsenide (InAs), indium phosphide (InP), gallium arsenide (GaAs), gallium antimonide (GaSb), etc. The first semiconductor substrate 110 may include a conductive region such as, for example, a well doped with impurities.

The first device layer 120 may be formed on one side of the first semiconductor substrate 110. The first device layer 120 may include a semiconductor device. The first device layer 120 may include various microelectronic devices, for example, a metal-oxide-semiconductor field effect transistor (MOSFET) such as a complementary metal-oxide-semiconductor (CMOS) transistor, system large scale integration (LSI), flash memory, DRAM, SRAM, EEPROM, PRAM, MRAM, or RERAM, an imaging sensor such as a CMOS imaging sensor (CIS), a micro-electro-mechanical system (MEMS), an active device, a passive device, etc. The one side of the first semiconductor substrate 110 on which the first device layer 120 is formed may be referred to as an active side (or a front side) of the first semiconductor substrate 110, and the other side of the first semiconductor substrate 110 opposite to the active side may be referred to as an inactive side (or a back side) of the first semiconductor substrate 110.

The first wiring layer 130 of the first semiconductor chip 100 may be disposed on the active side of the first semiconductor substrate 110. For example, the first wiring layer 130 of the first semiconductor chip 100 may be disposed on the first device layer 120. The first wiring layer 130 may include a wiring pattern to which a signal and/or power is transmitted and a wiring insulating layer surrounding the wiring pattern, but these are omitted from the drawing for convenience of explanation. The wiring pattern may be electrically connected to at least some of semiconductor devices of the first device layer 120 and/or at least some of the first through electrodes 112. For example, at least some of the first through electrodes 112 may be electrically connected to the wiring pattern of the first wiring layer 130 to be used to transmit a signal and/or power.

The first semiconductor chip 100 may further include a back-side wiring layer (not illustrated) disposed on the inactive side of the first semiconductor substrate 110. In this case, the first wiring layer 130 disposed on the active side of the first semiconductor substrate 110 may be used to transmit a signal, and the back-side wiring layer disposed on the inactive side of the first semiconductor substrate 110 may be used to transmit power.

For example, the back-side wiring layer of the first semiconductor chip 100 may form a back-side power delivery network (BSPDN). In this case, the back-side wiring layer may be electrically connected to the semiconductor device of the first device layer 120 through the first through electrodes 112 and buried power rails (not illustrated) electrically connected to the first through electrodes 112.

The first semiconductor chip 100 may further include a redistribution layer disposed on the first wiring layer 130 and/or the back-side wiring layer.

In FIG. 1, the first semiconductor chip 100 may be disposed such that the active side of the first semiconductor substrate 110 faces downward (e.g., along the Z direction) and an inactive side of the first semiconductor substrate 110 faces upward (e.g., along the Z direction). However, aspects are not limited thereto, and each of the first semiconductor chips 100 may be disposed such that the active side of the first semiconductor substrate 110 faces upward and the inactive side of the first semiconductor substrate 110 faces downward.

The plurality of second semiconductor chips 200 may be disposed on the first semiconductor chip 100. For example, the plurality of second semiconductor chips 200 may be sequentially stacked on the first semiconductor chip 100. Throughout this description, a second semiconductor chip disposed at a lowermost end among the plurality of second semiconductor chips 200 may be referred to as a lowermost second semiconductor chip 200L, and a second semiconductor chip disposed at an uppermost end may be referred to as an uppermost second semiconductor chip 200H. Each of the plurality of second semiconductor chips 200 may include a second semiconductor substrate 210, one or more second through electrodes 212 formed through the second semiconductor substrate 210, a second device layer 220, and a second wiring layer 230.

The second semiconductor substrate 210 may include the same or similar material to that of the first semiconductor substrate 110. The second device layer 220 may be formed on one side of the second semiconductor substrate 210. The second device layer 220 may include a semiconductor device. The second device layer 220 may include, for example, various microelectronic devices that may be included in the first device layer 120 described above. The one side of the second semiconductor substrate 210 on which the second device layer 220 is formed may be referred to as an active side (or a front side) of the second semiconductor substrate 210, and the other side of the second semiconductor substrate 210 opposite to the active side may be referred to as an inactive side (or a back side) of the second semiconductor substrate 210.

The second wiring layer 230 of the second semiconductor chip 200 may be disposed on the active side of the second semiconductor substrate 210. For example, the second wiring layer 230 of the second semiconductor chip 200 may be disposed on the second device layer 220. Although not illustrated, the second wiring layer 230 of the second semiconductor chip 200 may include a wiring pattern to which a signal and/or power is transmitted and a wiring insulating layer surrounding the wiring pattern. The wiring pattern may be electrically connected to at least some of the semiconductor devices of the second device layer 220 and/or at least some of the second through electrodes 212. The second semiconductor chip 200 may further include a redistribution layer disposed on the second wiring layer 230.

In the semiconductor package 10a, the plurality of second semiconductor chips 200 may be disposed such that the active side of the second semiconductor substrate 210 faces downward and the inactive side of the second semiconductor substrate 210 faces upward. For example, in the semiconductor package 10a, the plurality of second semiconductor chips 200 may be disposed such that the active side of the second semiconductor substrate 210 faces the first semiconductor chip 100. However, aspects are not limited thereto, and each of the plurality of second semiconductor chips 200 may also be disposed such that the active side of the second semiconductor substrate 210 faces upward and the inactive side of the second semiconductor substrate 210 faces downward.

Each of the second through electrodes 212 formed through the second semiconductor substrate 210 may be electrically connected to at least some of the first through electrodes 112 and/or at least some of the second through electrodes 212 of the other second semiconductor chip 200. For example, the second through electrodes 212 included in each of the plurality of second semiconductor chips 200 may be electrically connected to the second through electrodes 212 included in the adjacent second semiconductor chip 200. In addition, at least some of the plurality of second through electrodes 212 included in the lowermost second semiconductor chip 200L may be electrically connected to the plurality of first through electrodes 112 included in the first semiconductor chip 100.

First chip-to-chip bonding layers 410 and 420L may be interposed between the first semiconductor chip 100 and the plurality of second semiconductor chips 200. The first chip-to-chip bonding layers 410 and 420L may include first chip-to-chip connection members 412 and 422L and first chip-to-chip insulating layers 414 and 424 surrounding the first chip-to-chip connection members 412 and 422L. The first chip-to-chip connection members 412 and 422L may electrically connect the first through electrodes 112 and the second through electrodes 212 (e.g., the second through electrodes 212 included in the lowermost second semiconductor chip 200L). For example, the first through electrodes 112 and the second through electrodes 212 may be electrically connected to each other through the first chip-to-chip connection members 412 and 422L. The first chip-to-chip connection members 412 and 422L may be chip interconnection terminals, formed of a conductive material.

The first chip-to-chip bonding layers 410 and 420L may be formed by coupling or connecting a first bonding layer (e.g., layer 410 prior to coupling with layer 420L) and a second bonding layer (e.g., layer 420L prior to coupling with layer 410) that face each other. For example, the first bonding layer may be formed on the first semiconductor chip 100, and the first bonding layer (e.g., layer 410 prior to coupling with layer 420L) may include first bonding pads 412 and first insulating layers 414 surrounding the first bonding pads 412. In addition, a lowermost second bonding layer may be formed below the lowermost second semiconductor chip 200L, and the lowermost second bonding layer (e.g., layer 420L prior to coupling with layer 410) may include second bonding pads 422L and second insulating layers 424 surrounding the second bonding pads 422L. The first chip-to-chip bonding layers 410 and 420L may be formed by coupling or connecting the first bonding layer formed above the first semiconductor chip 100 and the lowermost second bonding layer formed below the lowermost second semiconductor chip 200L.

The first chip-to-chip bonding layers 410 and 420L may be formed by coupling the first bonding layer and the lowermost second bonding layer using a hybrid bonding method. For example, the first chip-to-chip connection members 412 and 422L may be formed by the thermal expansion of the first bonding pads 412 and the second bonding pads 422L coming into contact, and by the diffusion and bonding of the metal atoms included in the first bonding pads 412 and the second bonding pads 422L. In addition, in this example, the first chip-to-chip insulating layers 414 and 424 may be formed by the thermal expansion of the first insulating layers 414 and the second insulating layers 424 coming into contact, and by the diffusion and bonding of the atoms included in the first insulating layers 414 and the second insulating layers 424.

Second chip-to-chip bonding layers 420 and 430 may be interposed between the plurality of second semiconductor chips 200. The second chip-to-chip bonding layers 420 and 430 may include second chip-to-chip connection members 422 and 432 and second chip-to-chip insulating layers 424 and 434 surrounding the second chip-to-chip connection members 422 and 432. The second chip-to-chip connection members 422 and 432 may electrically connect the second through electrodes 212 of two adjacent second semiconductor chips 200-1 and 200-2 among the plurality of second semiconductor chips 200 to each other. For example, the plurality of second through electrodes 212 included in the two adjacent second semiconductor chips 200-1 and 200-2 may be electrically connected to each other through the second chip-to-chip connection members 422 and 432.

The second chip-to-chip bonding layers 420 and 430 may be formed by coupling or connecting a second bonding layer (e.g., layer 420 prior to coupling with layer 430) and a third bonding layer (e.g., layer 430 prior to bonding with layer 420) that face each other. For example, the second bonding layer may be formed below each of the plurality of second semiconductor chips 200. Each of the second bonding layers (e.g., each of layers 420 prior to coupling with layers 430) may include second bonding pads 422 electrically connected to the second through electrodes 212 included in the second semiconductor chip 200 disposed on the second bonding layer, and the second insulating layers 424 surrounding the second bonding pads 422. In addition, the third bonding layer 430 may be formed above each of the plurality of second semiconductor chips 200. Each of the third bonding layers (e.g., each of layers 430 prior to bonding with layers 420) may include third bonding pads 432 electrically connected to the second through electrodes 212 included in the second semiconductor chip 200 disposed below the third bonding layer, and third insulating layers 434 surrounding the third bonding pads 432. The second chip-to-chip bonding layers 420 and 430 may be formed by coupling or connecting the second bonding layer formed below an upper one 200-1 of the two adjacent second semiconductor chips 200-1 and 200-2, and the third bonding layer formed above a lower one 200-2 of the two adjacent second semiconductor chips 200-1 and 200-2.

The second chip-to-chip bonding layers 420 and 430 may be formed by coupling the second bonding layer and the third bonding layer by the hybrid bonding method described above. For example, the second chip-to-chip connection members 422 and 432 may be formed by diffuse bonding of the second bonding pads 422 and the third bonding pads 432, and the second chip-to-chip insulating layers 424 and 434 may be formed by diffuse bonding of the second insulating layers 424 and the third insulating layers 434.

The semiconductor package 10a may further include a dummy chip 300 disposed on the plurality of second semiconductor chips 200. For example, the semiconductor package 10a may include the dummy chip 300 disposed on the uppermost second semiconductor chip 200H. The dummy chip 300 may include the same or similar material as a material (e.g., silicon, germanium, etc.) included in the first semiconductor substrate 110 and the second semiconductor substrate 210. In an example, the dummy chip 300 may include only the same material (e.g., silicon, germanium, etc.) as the material included in the first semiconductor substrate 110 and the second semiconductor substrate 210. For example, the dummy chip 300 may be at least a portion of a bare wafer.

Third chip-to-chip bonding layers 430H and 440 may be interposed between the uppermost second semiconductor chip 200H and the dummy chip 300. The third chip-to-chip bonding layers 430H and 440 may insulate the uppermost second semiconductor chip 200H from the dummy chip 300. The third chip-to-chip bonding layers 430H and 440 may be formed by coupling or connecting a third bonding layer 430H and a fourth bonding layer 440 that face each other. For example, the uppermost third bonding layer 430H including the third insulating layers 434 may be formed above the uppermost second semiconductor chip 200H, and the fourth bonding layer 440 including an insulating material may be formed below the dummy chip 300. The third chip-to-chip bonding layers 430H and 440 may be formed by coupling or connecting the uppermost third bonding layer 430 and the fourth bonding layer 440 by means of any bonding method such as diffusion bonding, thermo-compression bonding, etc.

According to some aspects, the dummy chip 300 and the third chip-to-chip bonding layers 430H and 440 may be omitted. In some aspects in which the dummy chip 300 and the third chip-to-chip bonding layers 430H and 440 are omitted, the second through electrodes 212 may be omitted from the uppermost second semiconductor chip 200H. In addition, the second chip-to-chip connection members 422 and 432 included in the second chip-to-chip bonding layers 420 and 430 adjacent to the uppermost second semiconductor chip 200H may be electrically connected to the second wiring layer 230 (and/or redistribution layer formed on the second wiring layer 230) of the uppermost second semiconductor chip 200H.

The wiring patterns and connection members (e.g., bonding pads) included in the semiconductor package 10a may include, for example, a metal material such as copper (Cu), aluminum (Al), or tungsten (W). The wiring patterns may include a barrier layer for wiring and a metal layer for wiring. The barrier layer for wiring may include, for example, a metal, a metal nitride, or an alloy thereof, and the metal layer for wiring may include, for example, at least one metal selected from copper (Cu), aluminum (Al), tungsten (W), titanium (Ti), tantalum (Ta), ruthenium (Ru), or manganese (Mn).

For example, the wiring insulating layers in the wiring layer included in the semiconductor package 10a may include silicon oxide, silicon nitride, silicon oxynitride, an insulating material having a lower dielectric constant than silicon oxide, or a combination thereof.

For example, the insulating layers in the bonding layer included in the semiconductor package 10a may include silicon oxide, silicon nitride, silicon oxynitride, an insulating material having a lower dielectric constant than silicon oxide, a polymer material, or a combination thereof. For example, the polymer material may include benzocyclobutene (BCB), polyimide (PI), polybenzoxazole (PBO), silicon, acrylate, or epoxy, etc.

For example, the through electrodes included in the semiconductor package 10a may be formed of a through silicon via (TSV). Each of the through electrodes may include a conductive plug formed through the substrate and a conductive barrier layer surrounding the conductive plug. For example, the conductive plug may have a shape of a cylindrical column, and the conductive barrier layer may have a cylindrical shape surrounding a sidewall of the conductive plug. A via insulating layer may be interposed between each through electrode and the substrate to surround the sidewall of the through electrode. Each through electrode may be formed in any one of a via-first, via-middle, or via-last structure. At least some of the through electrodes included in the semiconductor package 10a may be used as electrodes for transmitting signals, and at least some of the through electrodes included in the semiconductor package 10a may be used as electrodes for transmitting power.

At least some semiconductor chips included in the semiconductor package 10a may be encapsulated using a molding member 510. For example, the semiconductor package 10a may further include the molding member 510 surrounding side surfaces of the plurality of second semiconductor chips 200. For example, the molding member 510 may include organic molding members such as Epoxy Molding Compound (EMC) and/or inorganic molding members such as silicon oxide, silicon nitride, silicon oxynitride, an insulating material with a lower dielectric constant than silicon oxide, or a combination thereof.

The semiconductor package 10a may further include package connection terminals 600 disposed below the first semiconductor chip 100. A redistribution layer may be interposed between the first semiconductor chip 100 and the package connection terminals 600. For example, the package connection terminals 600 may be solder balls, bumps, etc. At least some of the package connection terminals 600 may be electrically connected to at least some of the first through electrodes 112 and used for transmitting a signal. In addition, at least some other of the package connection terminals 600 may be electrically connected to at least some other of the plurality of first through electrodes 112 and used for transferring power.

The semiconductor package 10a may further include a substrate (e.g., a package substrate and/or an interposer, etc.), and the first semiconductor chip 100 and the plurality of second semiconductor chips 200 may be disposed on the substrate. In this case, pads formed on the substrate may be electrically connected to the package connection terminals 600.

At least one of the first semiconductor chip 100 or the plurality of second semiconductor chips 200 may be a memory chip. For example, the semiconductor package 10a may include a High Bandwidth Memory (HBM). In this case, the first semiconductor chip 100 may be a buffer die, a host die, or a logic die for controlling the plurality of second semiconductor chips 200, and the plurality of second semiconductor chips 200 may be core dies including memory cells.

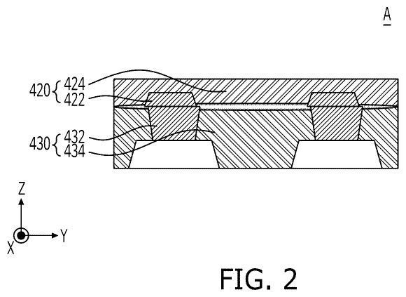

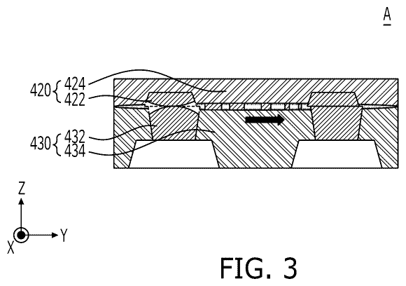

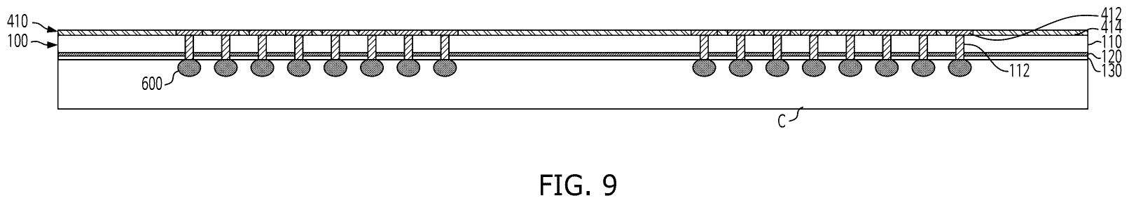

FIGS. 2 and 3 are enlarged views illustrating an example of a void occurring in an area A of FIG. 1, which includes second chip-to-chip bonding layers 420 and 430, during a test on the semiconductor package 10a. When the semiconductor package manufacturing (illustrated in FIGS. 9 to 20 below) is complete, a test on the semiconductor package may be performed. For example, by operating the semiconductor package under high temperature, high humidity, and electrical stress conditions, a test may be conducted on whether the semiconductor package can operate stably even in various environments.

For example, if moisture penetrates into the bonding layers 420 and 430 of the semiconductor package 10a during the test, a void may occur between the two bonding layers 420 and 430 that face each other (especially between the two insulating layers 424 and 434 that face each other), as illustrated in FIG. 2. In another example, moisture could penetrate into the bonding layers 420 and 430 during operation of the semiconductor package 10a, for example under environmental stress, and thereby also cause such a void between the bonding layers 420 and 430.

If a void occurs between the two bonding layers 420 and 430, a migration phenomenon may occur, in which metal atoms (e.g., copper atoms) included in the chip-to-chip connection members 422 and 432 move, as illustrated in FIG. 3. As a result, the electrical characteristics of the semiconductor package 10a may change and the mechanical and thermal stability may deteriorate, which may adversely affect the test and/or operation of the semiconductor package 10a. For these reasons, it is important to prevent moisture penetration into the semiconductor package, as disclosed herein below.

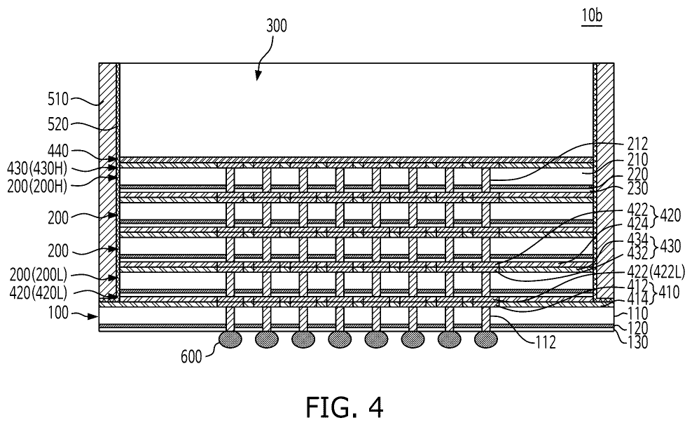

FIG. 4 is a diagram illustrating an example of a semiconductor package 10b. Most of the above description with reference to FIG. 1 may be applicable in the same or similar manner to the semiconductor package 10b of FIG. 4. Hereinbelow, the elements or operations already described above with reference to FIG. 1 will not be described or be briefly described, and the description will focus on additions/changes.

Referring to FIG. 4, the semiconductor package 10b may further include a moisture barrier layer 520. In this example, the moisture barrier layer 520 may be interposed between the plurality of second semiconductor chips 200 and the molding member 510. The moisture barrier layer 520 may surround the side surfaces (or side portions) of the plurality of second semiconductor chips 200. For example, the moisture barrier layer 520 may cover the side surfaces of the plurality of second semiconductor chips 200, side surfaces of the second chip-to-chip bonding layers 420 and 430 interposed between the plurality of second semiconductor chips 200, a side surface of the dummy chip 300, and/or side surfaces of the third chip-to-chip bonding layers 430H and 440 interposed between the uppermost second semiconductor chip 200H and the dummy chip 300.

The moisture barrier layer 520 may prevent moisture outside the semiconductor package 10b from penetrating into the semiconductor package 10b (e.g., between the second chip-to-chip bonding layers 420 and 430). A thickness of the moisture barrier layer 520 may be 5 μm or less, but is not limited thereto.

The moisture barrier layer 520 may include a material having low moisture permeability, excellent electrical insulation, and excellent thermal stability. The moisture barrier layer 520 may include an inorganic material. For example, the moisture barrier layer 520 may include an inorganic material including nitrogen atoms (N). For example, the moisture barrier layer 520 may include silicon nitride. The example of the material included in the moisture barrier layer 520 described above is only one possible example, and aspects are not limited thereto. The moisture barrier layer 520 may include any inorganic material and/or any material having low moisture permeability, excellent electrical insulation, and thermal stability.

In the semiconductor package 10b including the moisture barrier layer 520, the molding member 510 may cover an outer surface of the moisture barrier layer 520.

Because penetration of moisture into the semiconductor package 10b (e.g., between the second chip-to-chip bonding layers 420 and 430) is prevented by the moisture barrier layer 520, the semiconductor package 10b may operate stably under environmental stress (e.g., under test conditions such as high temperature, high humidity, electrical stress, etc.). For example, the occurrence of voids and/or migration, as illustrated in the examples of FIGS. 2 and 3, may be reduced or prevented.

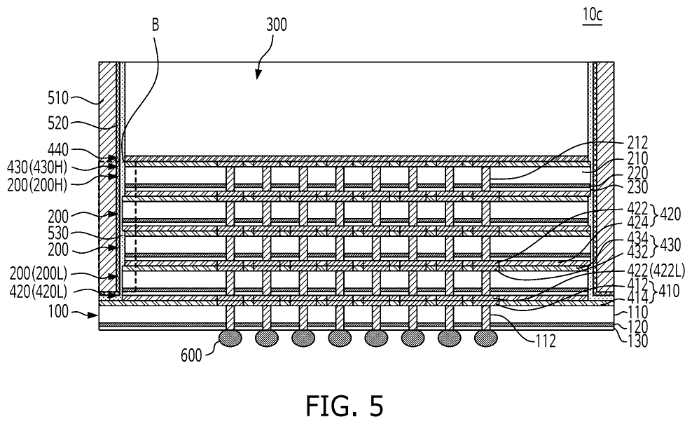

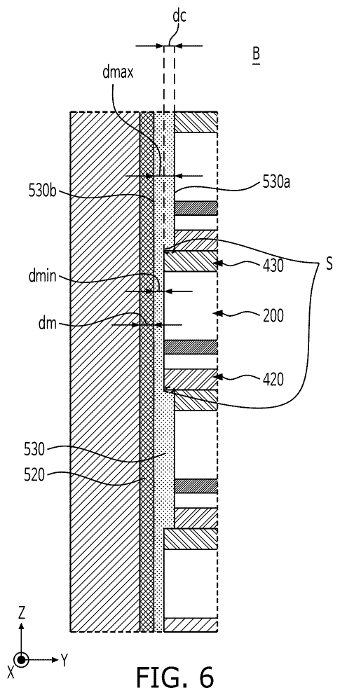

FIG. 5 is a diagram illustrating an example of a semiconductor package 10c according to embodiments of the present disclosure, and FIG. 6 is an enlarged view of an area B of FIG. 5. Most of the description provided above with reference to FIGS. 1 and 4 may be applicable in the same or similar manner to the semiconductor package 10c of FIGS. 5 and 6. Hereinbelow, the elements or operations already described above with reference to FIGS. 1 and 4 will not be described or be briefly described, and the description will focus on additions/changes.

Referring to FIGS. 5 and 6, a side step may occur between the stacked second semiconductor chips 200 due to size variation (e.g., within a tolerance) of the plurality of second semiconductor chips 200 themselves in the semiconductor package 10c, variation occurring in the process of arranging or stacking the plurality of second semiconductor chips 200, variation occurring in the bonding process of forming the bonding layer (e.g., the second chip-to-chip bonding layers 420 and 430), etc. For example, assuming all such variations remain within their respective manufacturing tolerances, they may nonetheless lead to one or more side step between the stacked second semiconductor chips 200. In an example, a size (dc) of the largest side step that can occur on one side surface of the plurality of stacked second semiconductor chips 200 may be about 20 μm or less, but aspects are not limited thereto. For example, the size de of the largest side step may be a length in a horizontal direction (e.g., the Y direction) of a longest side step in the horizontal direction. Stepped surfaces S may be exposed by the side steps between the plurality of second semiconductor chips 200. For example, the stepped surfaces S exposed by the side steps between the plurality of second semiconductor chips 200 may include at least a portion of upper or lower surfaces of the plurality of second semiconductor chips 200, the second bonding layer 420, and/or the third bonding layer 430.

In an example, such side steps between the stacked second semiconductor chips 200 could lead to the moisture barrier layer 520 not being applied evenly, causing a problem of moisture penetrating into the semiconductor package 10c. However, the semiconductor package 10c can prevent this problem, as disclosed herein below.

In order to facilitate uniform (e.g., even) application of the moisture barrier layer 520, the disclosed semiconductor package 10c may further include a step cover layer 530 covering side portions of the plurality of second semiconductor chips 200. The step cover layer 530 may be interposed between the plurality of second semiconductor chips 200 and the moisture barrier layer 520. The step cover layer 530 may surround side surfaces of the plurality of second semiconductor chips 200. For example, the step cover layer 530 may cover the side surfaces of the plurality of second semiconductor chips 200, the side surfaces of the second chip-to-chip bonding layers 420 and 430 interposed between the plurality of second semiconductor chips 200, the side surface of the dummy chip 300, and/or the side surfaces of the third chip-to-chip bonding layers 430H and 440 interposed between the uppermost second semiconductor chip 200H and the dummy chip 300. The step cover layer 530 may be formed to cover the side steps that may occur between the plurality of second semiconductor chips 200. For example, the step cover layer 530 may further cover the stepped surfaces S exposed by the side steps between the plurality of second semiconductor chips 200.

The step cover layer 530 may have an inner surface 530a covering and contacting the side surfaces of the plurality of second semiconductor chips 200, the second chip-to-chip bonding layers 420 and 430, the dummy chip 300, and/or the third chip-to-chip bonding layers 430H and 440, as described above. Likewise, the step cover layer 530 may have an outer surface 530b interfacing with the moisture barrier layer 520, and which may be planar. Accordingly, the step cover layer 530 may present the moisture barrier layer 520 with a planar surface.

A maximum thickness (e.g., a maximum distance dmax between the inner surface 530a and outer surface 530b) of the step cover layer 530 may be equal to or greater than the size de of the largest side step that may occur on one side surface of the plurality of second semiconductor chips 200 so as to cover the side step that may occur between adjacent second semiconductor chips of the plurality of second semiconductor chips 200. For example, the size de of the largest side step may be a length in a horizontal direction (e.g., the Y direction) of a longest side step in the horizontal direction. Specifically, a minimum thickness (dmin) of the step cover layer 530 may be about 5 μm or more (e.g., between 5 μm and 20 μm), and the maximum thickness (dmax) of the step cover layer 530 may be greater than the minimum thickness, such as greater than 5 μm, and may be 40 μm or less (e.g., about 20 μm or more and 40 μm or less), but these thicknesses are not limited thereto. In addition, an average thickness (e.g., an average distance between the inner surface 530a and outer surface 530b) of the step cover layer 530 may be equal to or greater than a thickness (dm) of the moisture barrier layer 520, but is not limited thereto. The thicknesses described above may be thicknesses in a direction perpendicular to a surface on which the step cover layer 530 is formed, which may be a horizontal direction (e.g., the Y direction).

In some examples, if the chips vary in size, but are aligned differently, the average thickness may be an average of a thickness on each side of each respective chip (e.g., four thicknesses for each chip). For example, for a stack of N chips, the average thickness may be calculated as the sum of 4N thicknesses divided by 4N. In a case where all the chips are the same size, the average thickness may reduce to an average of the thickness on all four sides of a single respective chip (e.g., an average of four thicknesses). In some cases, this may further reduce to an average of the thickness on two opposite sides of a single respective chip.

The step cover layer 530 may include an organic material. For example, the step cover layer 530 may include benzocyclobutene (BCB), polyimide (PI), polybenzoxazole (PBO), Epoxy Molding Compound (EMC), resin, etc. These examples of materials included in the step cover layer 530 are only some of the possible examples, and aspects are not limited thereto.

In the semiconductor package 10c including the step cover layer 530, the moisture barrier layer 520 may cover the outer surface 530b of the step cover layer 530, and the molding member 510 may cover the outer surface of the moisture barrier layer 520.

Because the disclosed step cover layer 530 is configured to cover the side steps that may occur at the side portions of the plurality of second semiconductor chips 200, the moisture barrier layer 520 may be uniformly applied (e.g., on the outer surface 530b of the step cover layer 530) without lifting even when there is a step between the plurality of second semiconductor chips 200. Accordingly, moisture penetration into the semiconductor package 10c may be effectively prevented even when there is a step between the plurality of second semiconductor chips 200.

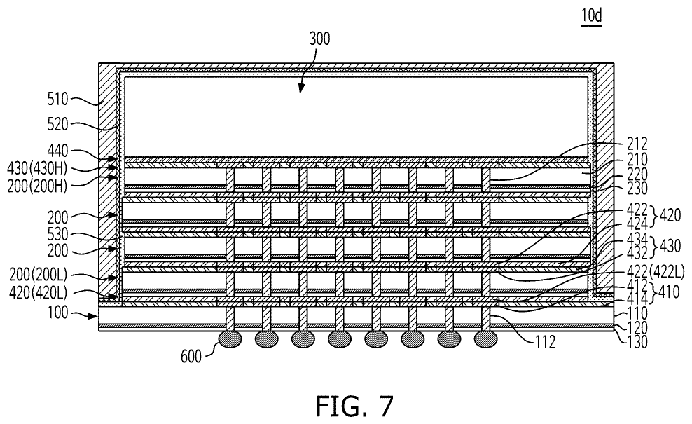

FIG. 7 is a diagram illustrating an example of a semiconductor package 10d, according to embodiments of the present disclosure. Most of the above description with reference to FIGS. 1 and 4 to 6 may be applicable in the same or similar manner to the semiconductor package of FIG. 7. Hereinbelow, the elements or operations already described above with reference to FIGS. 1 and 4 to 6 will not be described or be briefly described, and the description will focus on additions/changes.

Referring to FIG. 7, in the semiconductor package 10d, the step cover layer 530 may surround the side surfaces of the plurality of second semiconductor chips 200, the side surface of the dummy chip 300 disposed on the plurality of second semiconductor chips 200, and the upper surface of the dummy chip 300. For example, the step cover layer 530 may cover the side surfaces of the plurality of second semiconductor chips 200, side surfaces of the second chip-to-chip bonding layers 420 and 430 interposed between the plurality of second semiconductor chips 200, the side surface of the dummy chip 300, side surfaces of the third chip-to-chip bonding layers 430H and 440 interposed between the uppermost second semiconductor chip 200H and the dummy chip 300, and the upper surface of the dummy chip 300. In addition, the moisture barrier layer 520 may cover the outer surface of the step cover layer 530, and the molding member 510 may cover the outer surface of the moisture barrier layer 520.

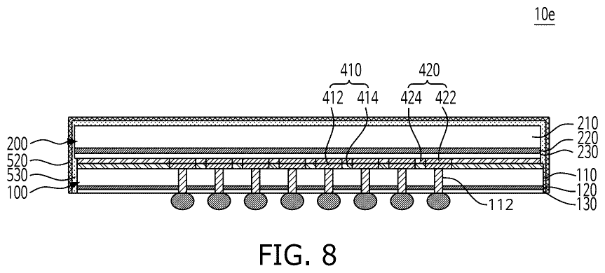

FIG. 8 is a diagram illustrating an example of a semiconductor package 10c, according to embodiments of the present disclosure. Most of the above description with reference to FIGS. 1 and 4 to 7 may be applicable in the same or similar manner to the semiconductor package 10e of FIG. 8. Hercinbelow, the elements or operations already described above with reference to FIGS. 1 and 4 to 7 will not be described or be briefly described, and the description will focus on additions/changes.

The semiconductor package 10e may include the first semiconductor chip 100 and the second semiconductor chip 200.

The first semiconductor chip 100 may include the first semiconductor substrate 110, the one or more first through electrodes 112 formed through the first semiconductor substrate 110, the first device layer 120, and the first wiring layer 130. In addition, the second semiconductor chip 200 may be disposed on the first semiconductor chip 100. The second semiconductor chip 200 may include the second semiconductor substrate 210, the second device layer 220, and the second wiring layer 230. The second wiring layer 230 of the second semiconductor chip 200 may be electrically connected to the first through electrodes 112 of the first semiconductor chip 100.

The first chip-to-chip bonding layer 410 and 420 may be interposed between the first semiconductor chip 100 and the second semiconductor chip 200. The first chip-to-chip bonding layer 410 and 420 may include the first chip-to-chip connection members 412 and 422 and the first chip-to-chip insulating layers 414 and 424 surrounding the first chip-to-chip connection members 412 and 422. The first chip-to-chip connection members 412 and 422 may electrically connect the first through electrodes 112 to the second wiring layer 230.

A side step may occur between the first semiconductor chip 100 and the second semiconductor chip 200 due to a difference in size between the first semiconductor chip 100 and the second semiconductor chip 200, a variation (e.g., within a tolerance) that may occur in the process of arranging or stacking the first and second semiconductor chips 100 and 200, a variation that may occur in the bonding process of forming a bonding layer (e.g., the first chip-to-chip bonding layer 410 and 420), etc. A stepped surface may be exposed by the side step between the first semiconductor chip 100 and the second semiconductor chip 200. For example, the stepped surface exposed by the side step between the first semiconductor chip 100 and the second semiconductor chip 200 may include at least a portion of upper or lower surfaces of the first semiconductor chip 100, the second semiconductor chip 200, the first bonding layer 410, and/or the second bonding layer 420.

The semiconductor package 10e may further include the step cover layer 530 and the moisture barrier layer 520.

The step cover layer 530 may cover a side portion of the first semiconductor chip 100 and a side portion of the second semiconductor chip 200. The step cover layer 530 may surround the side surface of the first semiconductor chip 100 and the side surface of the second semiconductor chip 200. For example, the step cover layer 530 may cover the side surface of the first semiconductor chip 100, the side surface of the second semiconductor chip 200, and the side surfaces of the first chip-to-chip bonding layer 410 and 420. The step cover layer 530 may be formed to cover a side step that may occur between the first semiconductor chip 100 and the second semiconductor chip 200. For example, it may cover the stepped surface exposed by the side step between the first semiconductor chip 100 and the second semiconductor chip 200. The step cover layer 530 may further cover an upper surface of the second semiconductor chip 200.

In the semiconductor package 10e including the step cover layer 530, the moisture barrier layer 520 may cover the outer surface of the step cover layer 530. Although not illustrated, the semiconductor package 10e may further include a molding member (not illustrated), and the molding member may cover the outer surface of the moisture barrier layer 520.

FIGS. 9 to 20 are views illustrating an example of a process of manufacturing a semiconductor package 10.

Referring to FIG. 9, a wafer including the first semiconductor chip 100 including the first semiconductor substrate 110, the first through electrodes 112 formed through the first semiconductor substrate 110, the first device layer 120 formed on the active side of the first semiconductor substrate 110, and the first wiring layer 130 disposed on the first device layer 120 may be prepared.

For example, the first semiconductor substrate 110 may include silicon or germanium, but is not limited thereto. For example, the first semiconductor substrate 110 may include a material having properties similar to silicon or germanium, such as silicon germanium, indium antimonide, lead telluride compound, indium arsenide, indium phosphide, gallium arsenide, gallium antimonide, etc. Furthermore, the first device layer 120 may include a semiconductor device. The first device layer 120 may include various microelectronic devices, for example, MOSFETs such as CMOS transistors, system LSI, flash memory, DRAM, SRAM, EEPROM, PRAM, MRAM, or RERAM, imaging sensors such as CIS, MEMS, active devices, passive devices, etc.

The package connection terminals 600 may be attached to a lower portion of the wafer that includes the first semiconductor chip 100. For example, the package connection terminals 600 may be solder balls, bumps, etc.

The wafer including the first semiconductor chip 100 attached with the package connection terminals 600 may be disposed (and attached) on a carrier C. For example, the first semiconductor chip 100 may be disposed (and attached) on the carrier C so that the active side (or the inactive side) of the first semiconductor chip 100 faces the carrier C.

The first bonding layer 410 including the first bonding pads 412 and the first insulating layers 414 surrounding the first bonding pads 412 may be formed on the wafer including the first semiconductor chip 100 (e.g., on the inactive side or active side of the first semiconductor chip 100). The first bonding pads 412 may be electrically connected to the first through electrodes 112 of the first semiconductor chip 100.

According to another aspect, the wafer including the first semiconductor chip 100 may be disposed on the carrier C after the first bonding layer 410 is formed on the wafer including the first semiconductor chip 100.

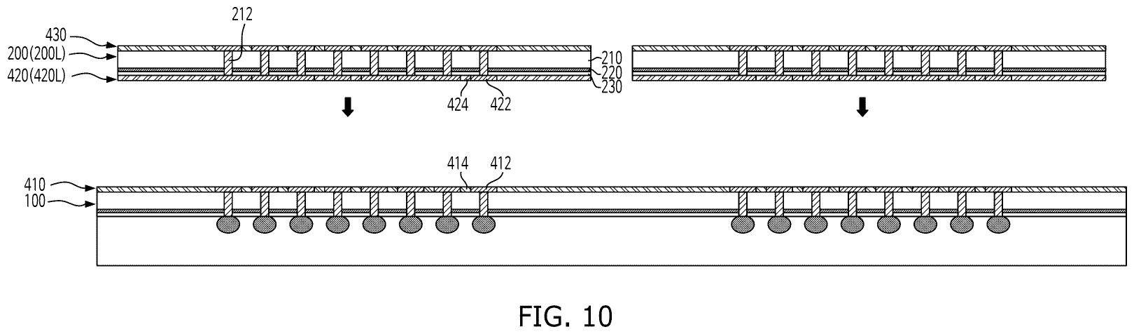

Referring to FIGS. 10 to 12, the plurality of second semiconductor chips 200 may be stacked on the first semiconductor chip 100. The plurality of second semiconductor chips 200 stacked on the first semiconductor chip 100 may include the second semiconductor substrate 210, the second device layer 220, and the second wiring layer 230, respectively. The second semiconductor substrate 210 may include the same or similar material to that of the first semiconductor substrate 110. Furthermore, the second device layer 220 may include a semiconductor device. The second device layer 220 may include, for example, various microelectronic devices that may be included in the first device layer 120 described above.

First, as illustrated in FIG. 10, the lowermost second semiconductor chip 200L may be stacked on the first semiconductor chip 100. The first semiconductor chip 100 and the lowermost second semiconductor chip 200L may be coupled to each other by a hybrid bonding method.

Specifically, the lowermost second bonding layer 420L including the second bonding pads 422 and the second insulating layers 424 surrounding the second bonding pads 422 may be formed below the lowermost second semiconductor chip 200L (e.g., on the active side or inactive side). The second bonding pads 422 may be electrically connected to the second through electrodes 212 of the lowermost second semiconductor chip 200L.

The lowermost second semiconductor chip 200L may be disposed on the first semiconductor chip 100 such that the lowermost second bonding layer 420L formed on the lowermost second semiconductor chip 200L faces the first bonding layer 410 formed on the first semiconductor chip 100. The first insulating layers 414 and the second insulating layers 424 that face each other may be bonded to form the first chip-to-chip insulating layers 414 and 424, and the first bonding pads 412 and the second bonding pads 422 that face each other may be bonded to form the first chip-to-chip connection members 412 and 422. For example, the first chip-to-chip bonding layers 410 and 420L may be formed by bonding the first bonding layer 410 and the second bonding layer 420L to each other. Accordingly, the first semiconductor chip 100 and the lowermost second semiconductor chip 200L may be coupled to each other.

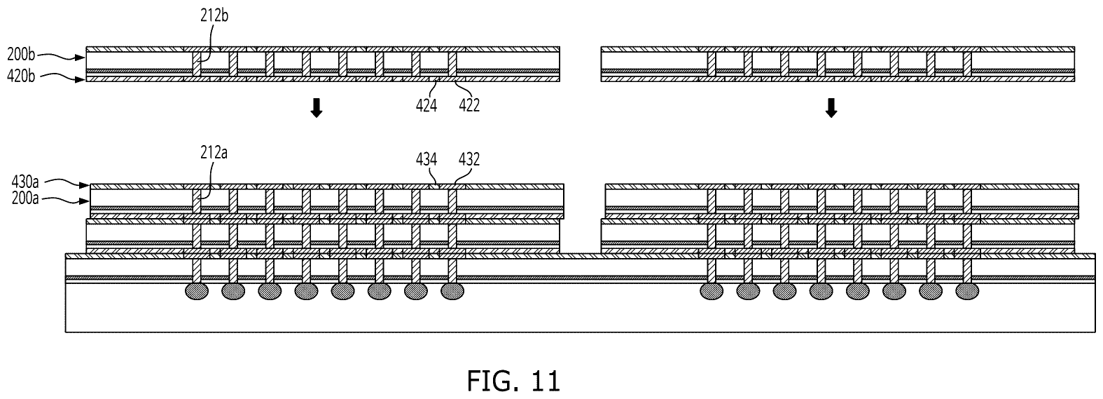

One or more second semiconductor chips 200 may be stacked on the lowermost second semiconductor chip 200L. For example, as illustrated in FIG. 11, a third bonding layer 430a including the third bonding pads 432 and the third insulating layers 434 surrounding the third bonding pads 432 may be formed above a second semiconductor chip 200a (hereinafter, referred to as a lower second semiconductor chip 200a) (e.g., on the inactive side or active side) that is one of the two adjacent second semiconductor chips 200a and 200b disposed on the lower side. The third bonding pads 432 included in the third bonding layer 430a may be electrically connected to second through electrodes 212a of the lower second semiconductor chip 200a.

In addition, a second bonding layer 420b including the second bonding pads 422 and the second insulating layers 424 surrounding the second bonding pads 422 may be formed below (e.g., on the active side or inactive side) a second semiconductor chip 200b (hereinafter, referred to as an upper second semiconductor chip 200b) that is one of the two adjacent second semiconductor chips 200a and 200b disposed on the upper side. The second bonding pads 422 included in the second bonding layer 420b may be electrically connected to second through electrodes 212b of the upper second semiconductor chip 200b.

The upper second semiconductor chip 200b may be disposed on the lower second semiconductor chip 200a such that the second bonding layer 420b formed below the upper second semiconductor chip 200b faces the third bonding layer 430a formed above the lower second semiconductor chip 200a. The second insulating layers 424 and the third insulating layers 434 that face each other may be bonded to form the second chip-to-chip insulating layers 424 and 434, and the second bonding pads 422 and the third bonding pads 432 that face each other may be bonded to form the second chip-to-chip connection members 422 and 432. For example, the second chip-to-chip bonding layers 420b and 430a may be formed by bonding the second bonding layer 420b and the third bonding layer 430a to each other. Thus, the two second semiconductor chips 200a and 200b disposed adjacent to each other may be coupled to each other.

While it is described above that the semiconductor chips are coupled to each other by the hybrid bonding method, aspects are not limited thereto. For example, the semiconductor chips may be coupled with each other by any method such as thermo-compression bonding method, etc.

The dummy chip 300 may be disposed on the plurality of second semiconductor chips 200. The dummy chip 300 may include the same or similar material as a material (e.g., silicon, germanium, etc.) included in the first semiconductor substrate 110 and the second semiconductor substrate 210. The dummy chip 300 may include only the same or similar material (e.g., silicon, germanium, etc.) as the material included in the first semiconductor substrate 110 and the second semiconductor substrate 210. For example, the dummy chip 300 may be at least a portion of a bare wafer.

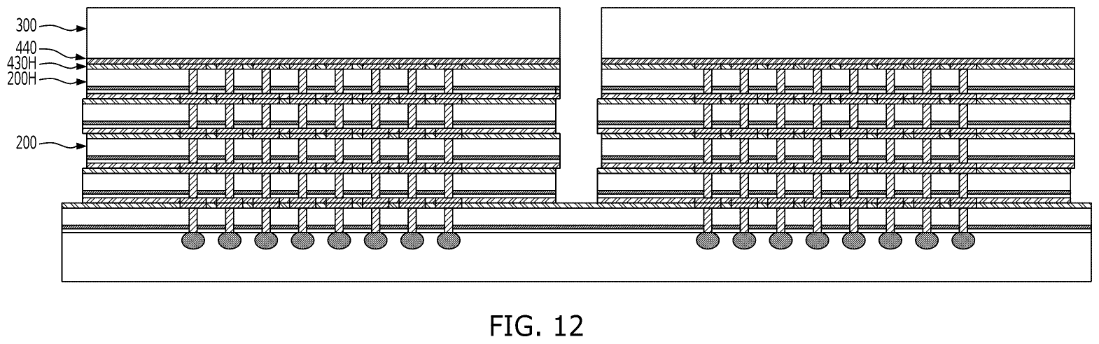

For example, as illustrated in FIG. 12, the uppermost third bonding layer 430H may be formed above the uppermost second semiconductor chip 200H, and the fourth bonding layer 440 may be formed below the dummy chip 300. The dummy chip 300 may be disposed on the uppermost second semiconductor chip 200H such that the fourth bonding layer 440 formed below the dummy chip 300 faces the uppermost third bonding layer 430H. In addition, the uppermost second semiconductor chip 200H and the dummy chip 300 may be coupled to each other by coupling or connecting the uppermost third bonding layer 430H and the fourth bonding layer 440 to each other.

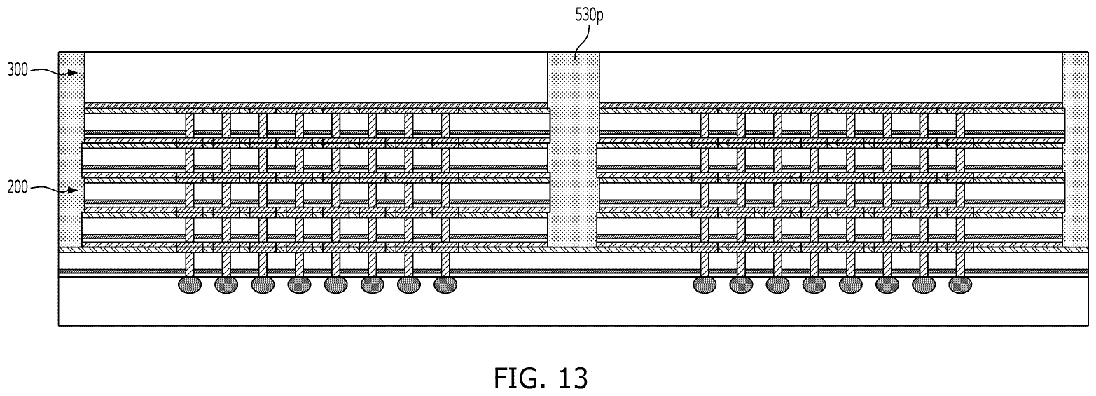

Referring to FIGS. 13 to 17, the step cover layer 530 surrounding the side portions of the plurality of second semiconductor chips 200 and the dummy chip 300 may be formed. Although FIGS. 13 to 17 illustrate that the step cover layer 530 surrounds only the side portions of the plurality of second semiconductor chips 200 and the dummy chip 300, aspects are not limited thereto. According to another aspect, the step cover layer 530 may also cover an upper portion of the dummy chip 300 disposed on the plurality of second semiconductor chips 200, as in the example of FIG. 7.

Specifically, first, as illustrated in FIG. 13, a solution 530p for forming the step cover layer may be applied on the side portions of the second semiconductor chips 200 and the side portion of the dummy chip 300.

The solution 530p for forming the step cover layer may include an organic material. For example, the solution 530p for forming the step cover layer may include benzocyclobutene (BCB), polyimide (PI), polybenzoxazole (PBO), Epoxy Molding Compound (EMC), resin, etc., but is not limited thereto.

The step cover layer 530 may be formed by removing a part of the applied solution 530p for forming the step cover layer or by molding the shape thereof.

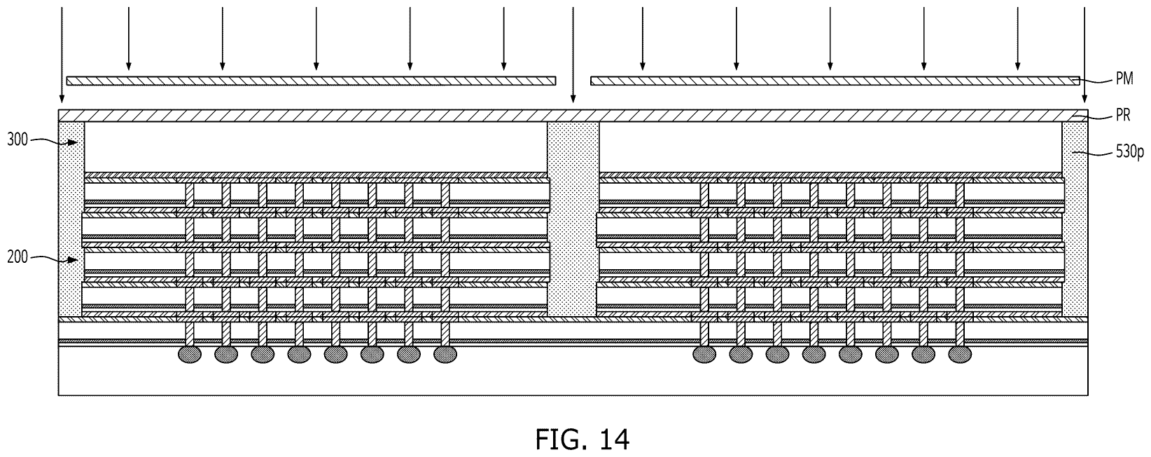

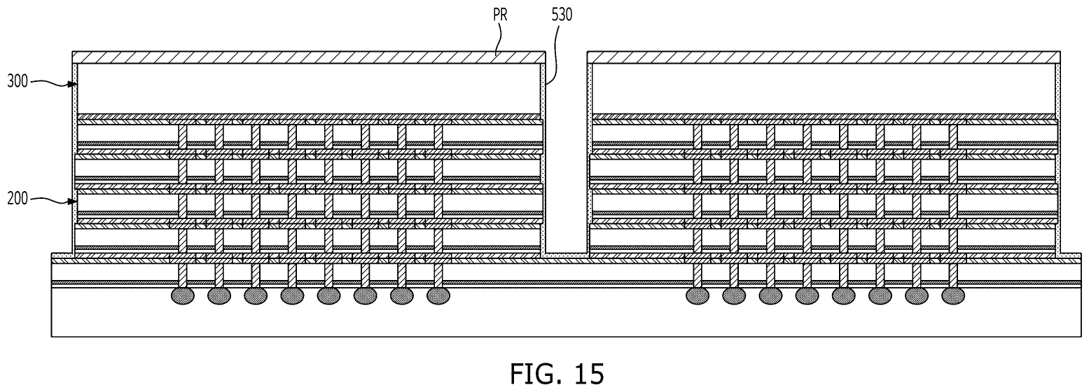

For example, as illustrated in FIGS. 14 and 15, the step cover layer 530 may be formed by removing a part of the solution 530p for forming the step cover layer by photolithography and etching processes. Specifically, as illustrated in FIG. 14, a photosensitive solution PR may be applied on the solution 530p for forming the step cover layer, a photomask PM having a pattern of portions to be removed or left may be disposed on the photosensitive solution PR, and light may be irradiated thereto. The properties of the portion of the photosensitive liquid PR irradiated with light may be changed, and by utilizing these properties, it is possible to selectively remove only a portion of the photosensitive liquid PR through which light is transmitted or not transmitted, as illustrated in FIG. 15. In addition, only a part of the solution 530p for forming the step cover layer, from which the photosensitive liquid PR is removed on the upper side thereof, may be selectively etched. The remaining photosensitive liquid PR may be removed. According to some aspects in which the step cover layer 530 is formed by the photolithography and etching processes, the solution 530p for forming the step cover layer may include benzocyclobutene (BCB), polyimide (PI), polybenzoxazole (PBO), etc., but is not limited thereto.

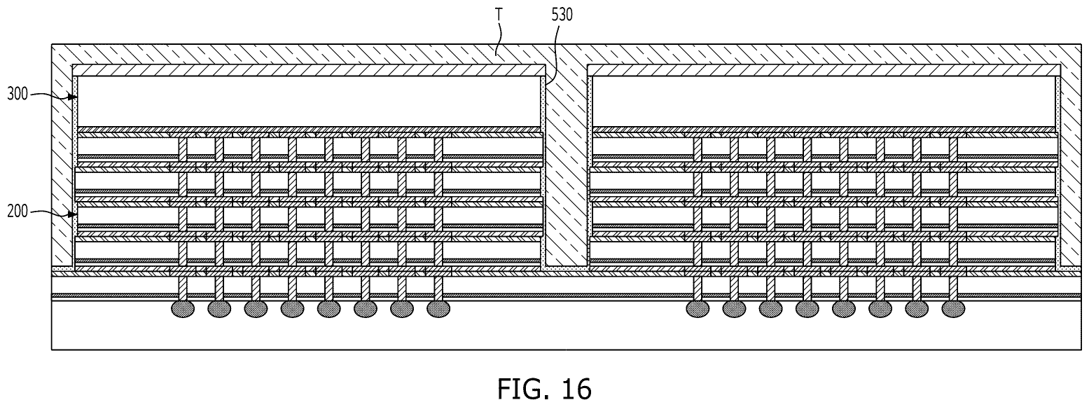

As another example, as illustrated in FIG. 16, the step cover layer 530 may be formed by molding the shape of the solution 530p for forming the step cover layer with a molding tool T. Specifically, the shape of the solution 530p may be molded as the applied solution 530p for forming the step cover layer is pressed by the molding tool T. According to some aspects in which the step cover layer 530 is formed by using the molding tool T, the solution 530p for forming the step cover layer may include Epoxy Molding Compound (EMC), resin, etc., but is not limited thereto.

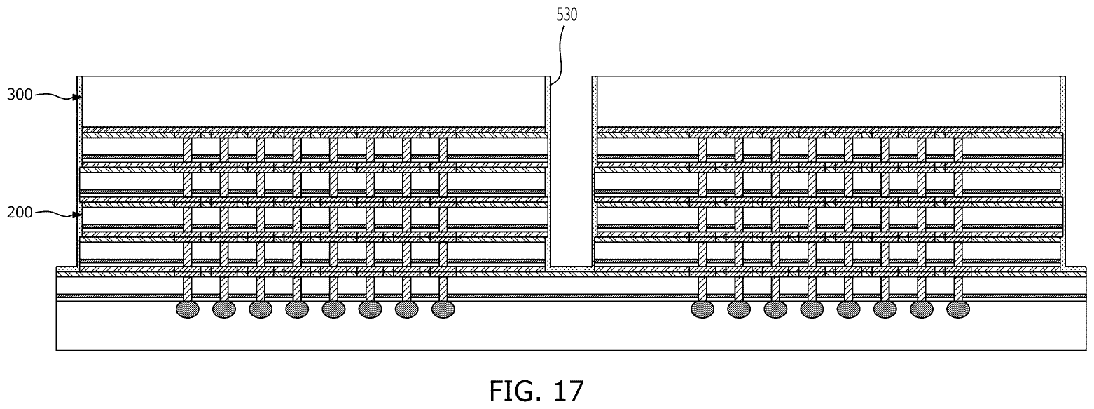

As a result, as illustrated in FIG. 17, the step cover layer 530 surrounding the side portions of the plurality of second semiconductor chips 200 and the side portion of the dummy chip 300 may be formed.

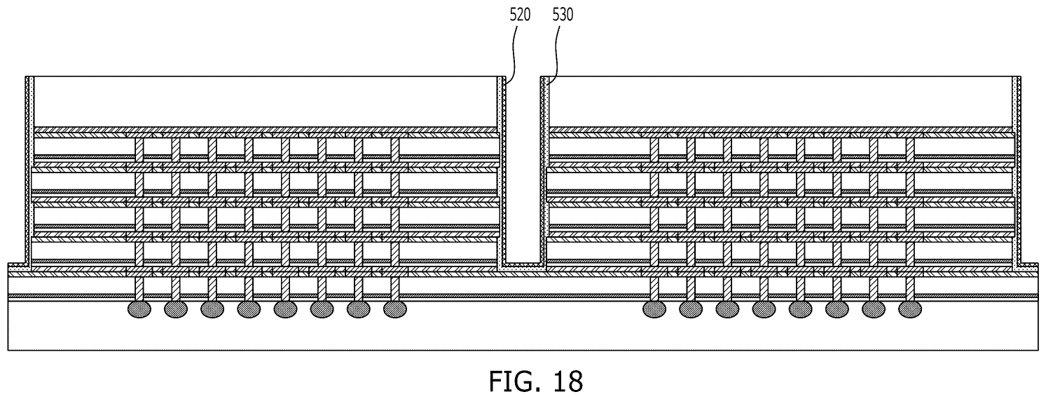

Referring to FIG. 18, the moisture barrier layer 520 covering the outer surface of the step cover layer 530 may be formed. For example, the moisture barrier layer 520 covering the outer surface of the step cover layer 530 may be formed by a deposition process. For example, the moisture barrier layer 520 may be formed by physical vapor deposition (PVD), chemical vapor deposition (CVD), atomic layer deposition (ALD), etc., but is not limited thereto, and the moisture barrier layer 520 may be formed by any process.

The moisture barrier layer 520 may include a material having low moisture permeability, excellent electrical insulation, and thermal stability. The moisture barrier layer 520 may include an inorganic material. For example, the moisture barrier layer 520 may include an inorganic material including nitrogen atoms (N). For example, the moisture barrier layer 520 may include silicon nitride, but is not limited thereto.

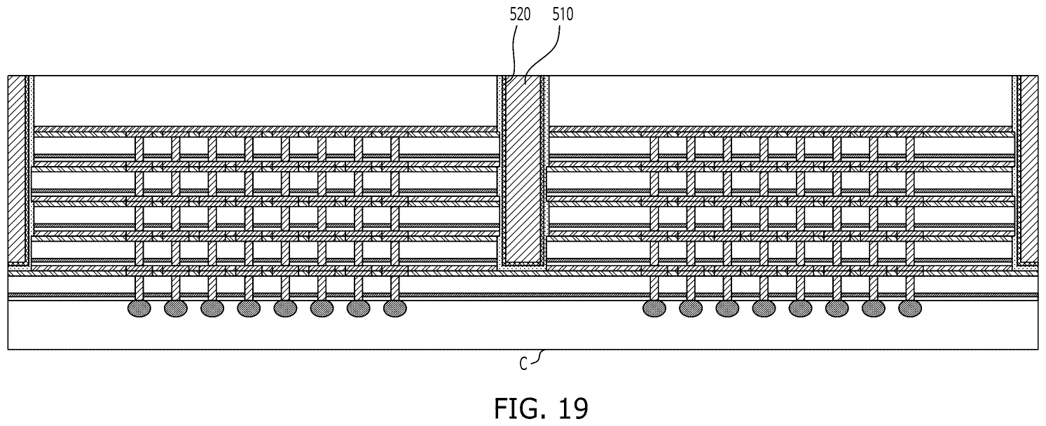

Referring to FIG. 19, the plurality of second semiconductor chips 200 and the dummy chip 300 may be encapsulated by the molding member 510. For example, the molding member 510 may be formed to cover the outer surface of the moisture barrier layer 520. The molding member 510 may include an organic material. For example, the molding member 510 may include an organic molding member such as Epoxy Molding Compound (EMC), but is not limited thereto.

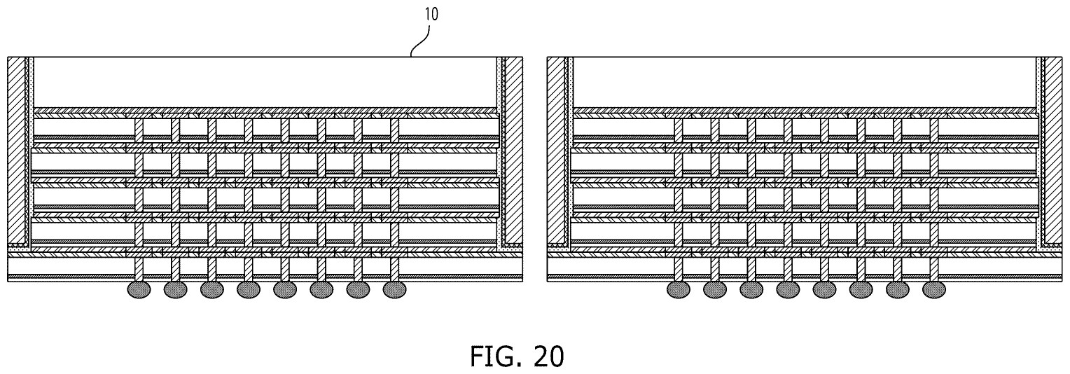

Referring to FIG. 20, the semiconductor package may be separated from the carrier C and diced. As a result, the semiconductor package 10 may be manufactured.

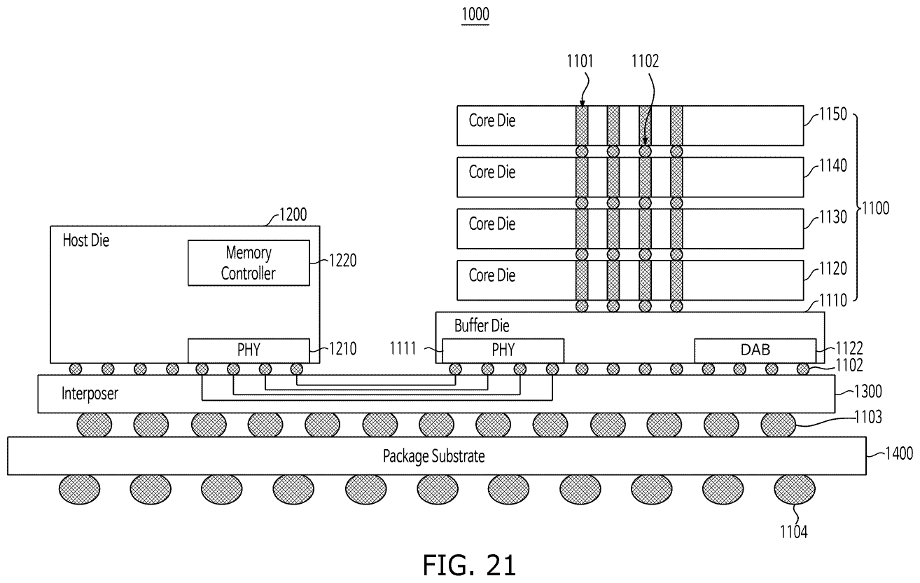

FIG. 21 is a diagram provided to explain an example of a semiconductor package 1000. A semiconductor system may include the semiconductor package 1000. Referring to FIG. 21, the semiconductor package 1000 may include a stacked memory device 1100, a host die 1200, an interposer 1300, and a package substrate 1400. The stacked memory device 1100 may include a buffer die 1110 and core dies 1120 to 1150. Each of the core dies 1120 to 1150 may include a memory cell array. The stacked memory device 1100 of the semiconductor package 1000 may include at least a portion of the semiconductor package having the structure described above with reference to FIGS. 1 to 8.

The buffer die 1110 may include a physical layer (PHY) 1111 and a direct access region (DAB) 1112. The physical layer 1111 may be electrically connected to a physical layer (PHY) 1210 of the host die 1200 through the interposer 1300. The stacked memory device 1100 may receive signals from the host die 1200 or transmit signals to the host die 1200 through the physical layer 1111.

The direct access region 1112 may provide an access path to transmit and receive signals to and from the stacked memory device 1100 without passing through the host die 1200. The direct access region 1112 may include conductive means (e.g., ports or pins) capable of direct communication with an external device (e.g., a test device). Signals and data received through the direct access region 1112 may be transmitted to the core dies 1120 to 1150 through TSVs. Data read from the core dies 1120 to 1150 for control of the core dies 1120 to 1150 may be transmitted to an external device through TSVs and the direct access region 1112. Accordingly, direct access and control of the core dies 1120 to 1150 may be performed.

The buffer die 1110 and the core dies 1120 to 1150 may be electrically connected to each other through TSVs 1101 and bumps 1102. The buffer die 1110 may receive signals provided to each channel from the host die 1200 through the bumps 1102 allocated for each channel. For example, the bumps 1102 may be micro-bumps. In another aspect, the bumps 1102 may be replaced with other conductive connection members.

The host die 1200 may execute applications supported by the semiconductor package 1000 using the stacked memory device 1100. For example, the host die 1200 may include at least one processor of a central processing unit (CPU), an application processor (AP), a graphic processing unit (GPU), a neural processing unit (NPU), a tensor processing unit (TPU), a vision processing unit (VPU), an image signal processor (ISP), and a digital signal processor (DSP) to execute specialized operations.

The host die 1200 may include the physical layer 1210 and a memory controller 1220. The physical layer 1210 may include input and output circuits for transmitting and receiving signals to and from the physical layer 1111 of the stacked memory device 1100. The host die 1200 may provide various signals to the physical layer 1111 through the physical layer 1210. The signals provided to the physical layer 1111 may be transmitted to the core dies 1120 to 1150 through interface circuits and the TSVs 1101 of the physical layer 1111.

The memory controller 1220 may control the overall operation of the stacked memory device 1100. The memory controller 1220 may transmit signals for controlling the stacked memory device 1100 to the stacked memory device 1100 through the physical layer 1210. Additionally or alternatively, the memory controller 1220 may be included in the buffer die 1110.

The interposer 1300 may connect the stacked memory device 1100 to the host die 1200. The interposer 1300 may connect the physical layer 1111 of the stacked memory device 1100 to the physical layer 1210 of the host die 1200, and may provide physical paths that are formed with conductive materials. Accordingly, the stacked memory device 1100 and the host die 1200 may be stacked on the interposer 1300 to transmit and receive signals to and from each other.

Bumps 1103 may be attached to an upper portion of the package substrate 1400, and a solder ball 1104 may be attached to a lower portion thereof. For example, the bumps 1103 may be flip-chip bumps. The interposer 1300 may be stacked on the package substrate 1400 through the bumps 1103. The semiconductor package 1000 may transmit and receive signals to and from other external packages or semiconductor devices through the solder ball 1104. For example, the package substrate 1400 may be a printed circuit board (PCB).

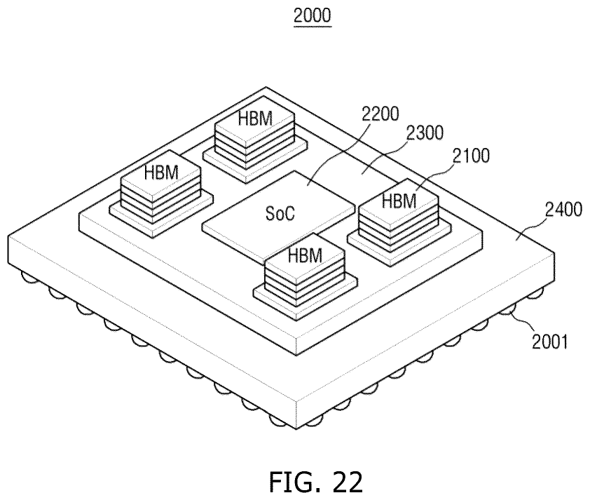

FIG. 22 is a diagram provided to explain an example implementation of a semiconductor package 2000. Referring to FIG. 22, the semiconductor package 2000 may include a plurality of stacked memory devices 2100 and a host die 2200. The stacked memory devices 2100 and the host die 2200 may be stacked on an interposer 2300, and the interposer 2300 may be stacked on a package substrate 2400. The semiconductor package 2000 may transmit and receive signals to and from other external packages or semiconductor devices through a solder ball 2001 attached to the lower portion of the package substrate 2400.

Each of the stacked memory devices 2100 may be implemented based on HBM standard. However, aspects are not limited thereto, and each of the stacked memory devices 2100 may be implemented based on a graphics double data rate (GDDR), a hybrid memory tube (HMC), or a wide I/O standard. Each of the stacked memory devices 2100 may correspond to the stacked memory device 1100 of FIG. 21.

The host die 2200 may be implemented as a system on chip (SoC) including at least one processor such as CPU, AP, GPU, NPU, etc. The host die 2200 may correspond to the host die 1200 of FIG. 21.

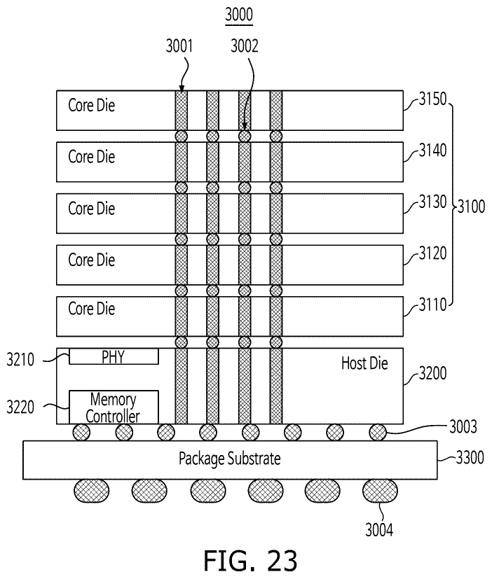

FIG. 23 is a diagram provided to explain an example of a semiconductor package 3000. Referring to FIG. 23, the semiconductor package 3000 may include a stacked memory device 3100, a host die 3200, and a package substrate 3300. The stacked memory device 3100 may include core dies 3110 to 3150. Each of the core dies 3110 to 3150 may include a memory cell array. The semiconductor package 3000 may be a buffer-less semiconductor package. In this case, the host die 3200 may also perform the function of the buffer die. Alternatively, at least one (e.g., 3110 of FIG. 23) of the core dies 3110 to 3150 may be replaced with a buffer die. The stacked memory device 3100 and the host die 3200 of the semiconductor package 3000 may include at least a portion of the semiconductor package having the structure described above with reference to FIGS. 1 to 8.

The host die 3200 may include a physical layer 3210 for communicating with the stacked memory device 3100 and a memory controller 3220 for controlling the overall operation of the stacked memory device 3100. In addition, the host die 3200 may include a processor for controlling the overall operation of the semiconductor package 3000 and executing an application supported by the semiconductor package 3000. For example, the host die 3200 may include at least one processor such as CPU, AP, GPU, NPU, etc.

The stacked memory device 3100 may be disposed on the host die 3200 based on TSVs 3001 and vertically stacked on the host die 3200. Accordingly, the core dies 3110 to 3150 and the host die 3200 may be electrically connected to each other through the TSVs 3001 and bumps 3002 without an interposer. For example, the bumps 3002 may be micro-bumps. In another aspect, the bumps 3002 may be replaced with other conductive connecting members.

Bumps 3003 may be attached to an upper portion of the package substrate 3300, and solder balls 3004 may be attached to a lower portion thereof. For example, the bumps 3003 may be flip-chip bumps. The host die 3200 may be stacked on the package substrate 3300 through the bumps 3003. The semiconductor package 3000 may transmit and receive signals to and from other external packages or semiconductor devices through the solder balls 3004.

Certain examples of the present disclosure have been described above for purposes of illustration only, and those skilled in the art with ordinary knowledge of the present disclosure will be able to make various modifications, changes and additions within the spirit and scope of the present disclosure, and such modifications, changes and additions should be construed to be included in a scope of the claims.

It should be understood that those of ordinary skill in the art to which the present disclosure pertains can make various substitutions, modifications and changes without departing from the technical spirit of the present disclosure, and thus, the present disclosure is not limited by the examples described above and the accompanying drawings.

What is claimed is:

1. A semiconductor package, comprising:
a first semiconductor chip;
a plurality of second semiconductor chips stacked on the first semiconductor chip;
a step cover layer surrounding side surfaces of the plurality of second semiconductor chips and covering side portions of the plurality of second semiconductor chips, wherein a maximum thickness of the step cover layer is 40 micrometers (μm) or less; and
a moisture barrier layer covering an outer surface of the step cover layer.

2. The semiconductor package according to claim 1, wherein:
the step cover layer includes an organic material, and
the moisture barrier layer includes an inorganic material.

3. The semiconductor package according to claim 1, wherein the moisture barrier layer includes an inorganic material including nitrogen.

4. The semiconductor package according to claim 1, wherein the maximum thickness of the step cover layer is equal to or greater than a size of a largest side step that occurs between adjacent second semiconductor chips of the plurality of second semiconductor chips, wherein the size of the largest side step comprises a length in a horizontal direction of a longest side step in the horizontal direction.

5. The semiconductor package according to claim 1, wherein an average thickness of the step cover layer is equal to or greater than a thickness of the moisture barrier layer.

6. The semiconductor package according to claim 1, wherein:
the first semiconductor chip includes:
a first semiconductor substrate; and
first through electrodes formed through the first semiconductor substrate, and
each of the plurality of second semiconductor chips includes:
a second semiconductor substrate; and
second through electrodes formed through the second semiconductor substrate.

7. The semiconductor package according to claim 6, further comprising a first chip-to-chip bonding layer interposed between the first semiconductor chip and the plurality of second semiconductor chips, wherein
the first chip-to-chip bonding layer includes:
a first chip-to-chip connection member electrically connecting at least some of the first through electrodes and the second through electrodes; and
a first chip-to-chip insulating layer surrounding the first chip-to-chip connection member.

8. The semiconductor package according to claim 6, further comprising a first bonding layer and a second bonding layer interposed between the first semiconductor chip and a lowermost second semiconductor chip of the plurality of second semiconductor chips, wherein:
the first bonding layer includes:
first bonding pads electrically connected to the first through electrodes; and
first insulating layers surrounding the first bonding pads,
the second bonding layer includes:
second bonding pads electrically connected to the second through electrodes of the lowermost second semiconductor chip disposed above the second bonding layer; and
second insulating layers surrounding the second bonding pads, and
the first bonding pads and the second bonding pads electrically connect the first through electrodes to the second through electrodes of the lowermost second semiconductor chip disposed above the second bonding layer.

9. The semiconductor package according to claim 6, further comprising a second chip-to-chip bonding layer interposed between the plurality of second semiconductor chips, wherein
the second chip-to-chip bonding layer includes:
second chip-to-chip connection members electrically connecting the second through electrodes of two adjacent second semiconductor chips of the plurality of second semiconductor chips to each other; and
second chip-to-chip insulating layers surrounding the second chip-to-chip connection members.

10. The semiconductor package according to claim 9, wherein the step cover layer surrounds the side surfaces of the plurality of second semiconductor chips and a side surface of the second chip-to-chip bonding layer.

11. The semiconductor package according to claim 6, wherein the plurality of second semiconductor chips includes a first chip and a second chip disposed on a lower side of the first chip, and
the semiconductor package further comprises a second bonding layer and a third bonding layer interposed between the plurality of second semiconductor chips, wherein:
the second bonding layer includes:
second bonding pads electrically connected to the second through electrodes of the first chip; and
second insulating layers surrounding the second bonding pads,
the third bonding layer includes:
third bonding pads electrically connected to the second through electrodes of the second chip; and
third insulating layers surrounding the third bonding pads, and
the second bonding pads and the third bonding pads electrically connect the first chip and the second chip to each other.

12. The semiconductor package according to claim 11, wherein
the step cover layer covers side surfaces of the plurality of second semiconductor chips and a stepped surface exposed by a side step between the plurality of second semiconductor chips, and
the stepped surface includes at least a portion of an upper surface or a lower surface of at least one of the second semiconductor chips, the second bonding layer, and the third bonding layer.

13. The semiconductor package according to claim 6, wherein the plurality of second semiconductor chips are disposed such that an active side of the second semiconductor substrate faces the first semiconductor chip.

14. The semiconductor package according to claim 1, further comprising a dummy chip disposed on the plurality of second semiconductor chips.

15. The semiconductor package according to claim 14, wherein the step cover layer surrounds the side surfaces of the plurality of second semiconductor chips and an upper surface of the dummy chip.

16. The semiconductor package according to claim 1, wherein the outer surface of the step cover layer is flat.

17. The semiconductor package according to claim 1, wherein the step cover layer covers at least a portion of a lower surface of the plurality of second semiconductor chips.

18. A semiconductor package, comprising:
a first semiconductor chip;
a second semiconductor chip disposed on the first semiconductor chip;
a step cover layer surrounding side surfaces of the first semiconductor chip and the second semiconductor chip, and covering side portions of the first semiconductor chip and the second semiconductor chip, wherein a maximum thickness of the step cover layer is 40 micrometers (μm) or less; and
a moisture barrier layer covering an outer surface of the step cover layer.

19. The semiconductor package according to claim 18, further comprising a first bonding layer and a second bonding layer interposed between the first semiconductor chip and the second semiconductor chip, wherein:
the first semiconductor chip includes:
a first semiconductor substrate; and
through electrodes formed through the first semiconductor substrate,
the second semiconductor chip includes:
a second semiconductor substrate; and
a wiring layer disposed on an active side of the second semiconductor substrate,
the first bonding layer includes:
first bonding pads electrically connected to the through electrodes; and
first insulating layers surrounding the first bonding pads,
the second bonding layer includes:
second bonding pads electrically connected to the wiring layer; and
second insulating layers surrounding the second bonding pads, and
the first bonding pads and the second bonding pads electrically connect the through electrodes and the wiring layer.

20. A semiconductor package, comprising:
a first semiconductor chip;
a plurality of second semiconductor chips stacked on the first semiconductor chip;
a dummy chip disposed on the plurality of second semiconductor chips;
a step cover layer including an organic material, wherein the step cover layer surrounds side surfaces of the plurality of second semiconductor chips and a side surface or upper surface of the dummy chip, and covers side portions of the plurality of second semiconductor chips;
a moisture barrier layer including an inorganic material, wherein the moisture barrier layer covers an outer surface of the step cover layer; and
a molding member including a second organic material, wherein the molding member covers an outer surface of the moisture barrier layer, wherein
the step cover layer covers the side surfaces of the plurality of second semiconductor chips and a stepped surface exposed by a side step between the plurality of second semiconductor chips.
